(19) United States
(12) Patent Application Publication
(10) Pub. No.: US 2019/0153589 A1
(43) Pub. Date: May 23, 2019

(54) Device and Method for Producing a Corrosion-Protected Steel Product

(71) Applicants: ThyssenKrupp Steel Europe AG, Duisburg (DE); thyssenkrupp AG, Essen (DE)

(72) Inventors: Stefan Peter Puls, Dortmund (DE); Bernd Schuhmacher, Dortmund (DE); Krasimir Nikolov, Dortmund (DE); Claus-peter Klages, Braunschweig (DE)

(21) Appl. No.: 16/092,510

(22) PCT Filed: Apr. 12, 2017
(86) PCT No.: PCT/EP2017/058722

§ 371 Date: Oct. 10, 2018

(30) Foreign Application Priority Data
Apr. 12, 2016 (DE) 10 2016 106 679.6

(51) Int. Cl. C23C 14/58; C23C 14/16; C23C 14/35; C23C 14/56

(52) U.S. Cl. CPC C23C 14/586; C23C 14/165; H01J 37/32018; C23C 14/562; C23C 14/35

(57) ABSTRACT

An apparatus for producing a corrosion-protected steel product, in particular a steel strip or steel sheet, is disclosed. The apparatus includes a device for plasma nitriding a steel substrate and a coating device for applying a metallic material to the steel substrate. A process for producing a corrosion-protected steel product, in particular a steel strip or steel sheet, is also disclosed, wherein a steel substrate is provided and nitrogen is diffused by plasma nitriding into the steel substrate, and wherein a metallic material is applied to the steel substrate.

### PRIOR ART

The present invention relates to an apparatus for producing a corrosion-protected steel product, in particular a steel strip or steel sheet, having a device for plasma nitriding a steel substrate, where the device for plasma nitriding comprises at least one hollow cathode space in which a hollow cathode glow discharge can be produced. The invention further relates to a process for producing a corrosion-protected steel product, in particular a steel strip or steel sheet, where a steel substrate is provided and nitrogen is diffused into the steel substrate by plasma nitriding and a plasma is provided by a hollow cathode glow discharge to effect plasma nitriding.

The invention is employed in the production of steel products configured as bipolar plates. Such bipolar plates are used in fuel cells, in particular in fuel cells having a proton exchange membrane (proton exchange membrane fuel cell, PEMPFC) in order to electrically contact membrane electrode assemblies (MEA). In addition, the bipolar plates conduct reaction gases to the reaction regions and conduct away the heat evolved and also water. The bipolar plates are subjected to very aggressive chemical conditions in the fuel cell and at the same time application of an electric potential, which can lead to corrosion of the bipolar plates. It is therefore necessary to protect such bipolar plates made of steel against corrosion. This can, for example, be effected by modification of the surface. Here, it is necessary for the corrosion protection not to significantly impair the contact resistance of the bipolar plate, so that low-ohm contacting of the membrane electrode assembly can be made possible.

The production of corrosion-protected bipolar plates can be carried out by plasma nitriding steel substrates. Here, by means of a plasma produced in a nitrogen atmosphere nitrogen atoms are embedded in a thin surface layer of the steel substrate. In the case of an austenitic steel substrate, the embedding of the nitrogen atoms into the austenite lattice leads to expansion and thus to formation of a dense outer layer of expanded austenite close to the surface. The bipolar plates which have been nitrided in this way have improved corrosion resistance.

DE 197 44 060 discloses a process for producing a corrosion-protected steel product, in which nitrogen is diffused by plasma nitriding into a strip-shaped steel substrate. The strip-shaped steel substrate is in this process conducted so that it itself forms a hollow cathode by means of which a hollow cathode glow discharge is produced. A nitrogen-containing plasma is provided by means of this glow discharge.

The known process makes it possible to produce corrosion-protected steel products having a low contact resistance within a short process time. However, it has been found to be a disadvantage in the process that an increase in the contact resistance can occur in the case of steel products of this type which under operating conditions are subjected to a change in their electric potential, for example bipolar plates, as a result of cathodic polarization. As a result, the steel products produced do not have the stability necessary for use as bipolar plate.

### DISCLOSURE OF THE INVENTION

In view of the above, it is an object of the present invention to make it possible to produce a corrosion-protected steel product which has increased stability, in particular to the influences of cathodic polarization.

The object is achieved by an apparatus for producing a corrosion-protected steel product, in particular a steel strip or steel sheet, having a device for plasma nitriding a steel substrate, where the device for plasma nitriding comprises at least one hollow cathode space in which a hollow cathode glow discharge can be produced and where the apparatus additionally comprises a coating device for applying a metallic material to the steel substrate.

The apparatus of the invention allows the plasma nitriding of the steel substrate to be combined with application of a metallic material. Nitrogen can be diffused into an outer zone close to the surface of the steel substrate by the device for plasma nitriding. A “nitriding layer” which has increased corrosion resistance can be formed. The metallic material applied can likewise diffuse into the steel substrate and/or form nitrides. This makes it possible to bring about simultaneous diffusion of the nitrogen and of the applied metal into the steel substrate and to promote the formation of nitrides. A surface which has improved corrosion resistance and a low contact resistance can be obtained by means of the process.

The apparatus can advantageously be used for producing steel products, in particular steel strips or steel plates, which serve as intermediate for the production of bipolar plates.

The device according to the invention for plasma nitriding comprises at least one hollow cathode space in which a hollow cathode glow discharge can be produced. A plasma having a homogeneous distribution can be produced in the hollow cathode space by means of the hollow cathode glow discharge. The use of a hollow cathode space also has the advantage that a plasma having a high plasma density can be obtained.

The hollow cathode space can be arranged within a hollow cathode. The hollow cathode space is preferably at least partly delimited by the steel substrate, so that the hollow cathode is at least partly formed by the steel substrate. For this purpose, it is possible to provide an apparatus for contacting the steel substrate so that the steel substrate can be connected to a prescribed potential, for example a ground potential, during plasma nitriding. The steel substrate particularly preferably delimits the hollow cathode space on two opposite sides. For example, the apparatus can comprise a transport device which conveys a strip-shaped steel substrate, for example a steel strip, in such a way that two sections of the steel substrate, separated by the hollow cathode space, are arranged essentially parallel. A steady-state hollow cathode glow discharge can be produced in the hollow cathode region between the two sections of the steel substrate being conveyed, for example by application of a DC or AC voltage.

The coating device is preferably configured as a sputtering deposition device. In sputtering deposition, atoms are knocked out of a target by ion bombardment and deposited on the steel substrate. As ion source of the sputtering deposition device, preference is given to using a hollow cathode space of the device for plasma nitriding.

In an advantageous embodiment, the sputtering deposition device has a magnetic field source by means of which a magnetic field can be produced in the hollow cathode space. The magnetic field can overlap with an electric field of the device for plasma nitriding, in particular an electric field of the hollow cathode, so that the ions of the plasma of the device for plasma nitriding are accelerated in the region before a target so that they can detach atoms from the target. The magnetic field source can, for example, be configured as a magnetron. The magnetic field source is preferably arranged outside the hollow cathode space, in particular directly adjoining the hollow cathode space.

An embodiment in which the sputtering deposition device comprises a target from which metal atoms can be detached, with the target being formed by the steel substrate, has been found to be particularly advantageous. Such a configuration is particularly advantageous when the apparatus is intended for producing strip-shaped steel products. It is possible to provide a transport device by means of which the strip-shaped steel substrate can be conveyed so that it delimits the hollow cathode space on two opposite sides. The magnetic field source can be arranged so that the magnetic field produced thereby brings about sputtering of metal atoms in a first section of the steel substrate delimiting the hollow cathode space. In a second section of the steel substrate delimiting the hollow cathode space, the sputtered metal atoms can be applied and diffused together with the nitrogen atoms into the steel substrate.

Preference is also given to the device for plasma nitriding comprising a guide roller by means of which the in particular strip-shaped steel substrate can be conducted in such a way that it delimits the hollow cathode space in an arc-like manner in the region of the guide roller. The steel substrate can lie against the guide roller so that spreading of the hollow cathode glow discharge to a side of the steel substrate facing the guide roller can be effectively prevented. It is in this way possible to provide a hollow cathode glow discharge having an increased discharge power, as a result of which an increased plasma nitriding rate can be achieved. The guide roller is particularly preferably configured so as to be coolable. It is possible to provide a cooling apparatus by means of which the guide roller can be cooled so that excessive heating of the steel substrate by the hollow cathode glow discharge can be countered.

In this context, it has been found to be particularly advantageous for a magnetic field source for producing a magnetic field to be arranged within the guide roller. This enables sputtering deposition in a hollow cathode space having an arc-like boundary, with the steel substrate forming a target out of which metal atoms can be knocked.

In a further preferred embodiment, the device for plasma nitriding comprises two hollow cathode spaces. The steel substrate can be able to be conveyed in such a way that it is introduced in succession into the two hollow cathode spaces, so that two successive diffusion operations can be carried out. It has in this case been found to be advantageous for one or more magnetic field sources by means of which a magnetic field can be produced in the two hollow cathode spaces to be provided. Different targets are preferably provided in the hollow cathode spaces, so that two different materials in succession can be applied to and optionally diffused into the steel substrate conveyed through the two hollow cathode spaces. For example, it is possible to configure the first hollow cathode space in such a way that a metallic material can be applied to the steel substrate and to configure the second hollow cathode space in such a way that carbon can be applied to the steel substrate.

In a further advantageous embodiment, the apparatus comprises a holding device by means of which the, in particular plate-shaped, steel substrate can be introduced into the apparatus in such a way that the steel substrate is arranged between two hollow cathode spaces and delimits the two hollow cathode spaces. In such a configuration, two opposite surfaces of the steel substrate can be subjected simultaneously to treatment by plasma nitriding and/or sputtering deposition. It is possible to apply the same material or two different materials to the two sides of the steel substrate.

In an advantageous embodiment, the apparatus comprises a preheating device by means of which the steel substrate can be preheated before plasma nitriding, so that the steel substrate has a temperature beneficial for the nitriding operation. The preheating device can be configured as resistive preheating device, inductive preheating device, plasma preheating device, electron beam preheating device, laser preheating device or infrared preheating device. The steel substrate can be preheated by means of the preheating device to a temperature in the range from 350° C. to 750° C., preferably to a temperature in the range from 420° C. to 470° C., particularly preferably to a temperature in the range from 440° C. to 460°, for example to 450° C.

A process for producing a corrosion-protected steel product, in particular a steel strip or steel sheet, where a steel substrate is provided and nitrogen is diffused by plasma nitriding into the steel substrate, wherein a plasma is provided by a hollow cathode glow discharge for plasma nitriding and wherein a metallic material is applied to the steel substrate, also contributes to achieving the object mentioned at the outset.

In this process, it is possible to achieve the same advantages as have been described above in connection with the apparatus of the invention for producing a corrosion-protected steel product.

The metallic material is advantageously applied by sputtering deposition. As target for sputtering deposition, it is possible to use either a target or the steel substrate itself. The metallic material preferably comprises a transition metal, in particular chromium, titanium, niobium, vanadium, tungsten, manganese, molybdenum, tantalum, zirconium, hafnium or yttrium, or aluminum. The term “transition metals” refers to the chemical elements having the atomic numbers 21 to 30, 39 to 48, 57 to 80 and 89 to 112 with the exception of iron (Fe, atomic number 26). As an alternative, the metallic material can consist exclusively of one of the abovementioned transition metals or metals.

In a preferred embodiment of the process, the metallic material is applied before nitrogen is diffused by plasma nitriding into the steel substrate. The application of the metallic material can be carried out in a separate process step preceding plasma nitriding. In this case, the metallic material is preferably applied in such a way that a thin, nitrogen-permeable layer is formed on the steel substrate and so the nitrogen can diffuse through the metallic material applied to the steel substrate in the subsequent process step of plasmas nitriding. The applied layer can, for example, have a layer thickness which is in the range below 500 nm, preferably in the range below 200 nm, particularly preferably in the range below 50 nm. The minimum layer thickness can be 5 nm. During plasma nitriding, both the metallic material applied and the nitrogen can diffuse into the steel substrate. A nitriding layer close to the surface and optionally nitrides can be formed.

In an alternative preferred embodiment of the process, the metallic material is applied while nitrogen is diffused by plasma nitriding into the steel substrate. This results in both the metallic material and the nitrogen being diffused into the steel substrate during application of the metallic material, resulting in a nitriding layer and optionally nitrides being able to be formed.

A further advantageous embodiment provides for carbon to be applied, preferably by sputtering deposition, to the steel substrate, in particular after nitrogen has diffused by plasma nitriding into the steel substrate. The carbon can be provided by means of a graphite target from which carbon atoms are detached by means of ion bombardment. The diffusion of carbon into the steel substrate leads to carbon doping which further improves the stabilization of the corrosion resistance and the contact resistance.

An embodiment in which the steel substrate is conveyed during the inward diffusion of nitrogen and the application of the metallic material, so that a continuous production operation is made possible is advantageous. Such a process is particularly advantageous when the steel substrate has a strip-shaped configuration.

According to the invention, a plasma is provided by a hollow cathode glow discharge for plasma nitriding. The hollow cathode glow discharge can be produced within a hollow cathode space which is at least partly delimited by the steel substrate, in particular the moving steel substrate.

In a constructionally advantageous embodiment, the hollow cathode glow discharge is provided by means of a pulsed DC voltage.

The steel substrate is preferably made of an austenitic and/or rusting- and acid-resistant steel. Such a steel substrate makes it possible to produce steel products configured as bipolar plates which are cheaper and more compact than carbon-based bipolar plates.

It has also been found to be advantageous for the steel substrate to be preheated before plasma nitriding, so that the steel substrate has a temperature beneficial for the nitriding operation. The steel substrate can, in particular, be preheated to a temperature in the range from 350° C. to 750° C., preferably to a temperature in the range from 420° C. to 470° C., particularly preferably to a temperature in the range from 440° C. to 460°, for example to 450° C. The preheating of the steel substrate before plasma nitriding can be carried out either before application of the metallic material or during application of the metallic material or after application of the metallic material. The preheating of the steel substrate before plasma nitriding can, for example, be carried out resistively, inductively, by means of a plasma, by means of an electron beam, by means of a laser and/or by means of infrared radiation (e.g. IR or NIR radiation).

In the process, the advantageous features described in connection with the apparatus for producing a corrosion-protected steel product can be used as an alternative to or in addition to the above-described advantageous embodiments.

Further details, features and advantages of the invention can be derived from the drawings and from the following description of preferred embodiments with the aid of the drawings. The drawings illustrate merely illustrative embodiments of the invention which do not restrict the scope of the invention.

### BRIEF DESCRIPTION OF THE FIGURES

FIG. 1 shows a flow diagram of a first working example of the process of the invention.

FIG. 2 shows a flow diagram of a second working example of the process of the invention.

FIG. 3 shows a first working example of an apparatus according to the invention in a schematic depiction.

FIG. 4 shows a second working example of an apparatus according to the invention in a schematic depiction.

FIG. 5 shows a third working example of an apparatus according to the invention in a schematic depiction.

FIG. 6 shows a fourth working example of an apparatus according to the invention in a schematic depiction.

FIG. 7 shows a fifth working example of an apparatus according to the invention in a schematic depiction.

FIG. 8 shows a sixth working example of an apparatus according to the invention in a schematic depiction.

FIG. 9 shows a depth profile of a corrosion-resistant steel product as per a first working example.

FIG. 10 shows a depth profile of a corrosion-resistant steel product as per a second working example.

FIG. 11 shows depth profiles of the corrosion-resistant steel products as per the first and second working examples.

FIG. 12 shows a depth profile of a corrosion-resistant steel product as per a third working example.

### EMBODIMENTS OF THE INVENTION

In the various figures, the same parts are always denoted by the same reference symbols and are therefore generally named or mentioned only once in each case.

The processes and apparatuses presented in the figures for producing a corrosion-protected steel product are particularly suitable for producing precursors configured as a steel strip or steel sheet which are used for producing bipolar plates for fuel cells, in particular proton exchange membrane fuel cells (PEMFC).

A steel substrate which is preferably configured as an austenitic, rusting- and acid-resistant steel substrate (RS steel) is used as starting material. The steel substrate can be present as steel strip or as thin steel sheet.

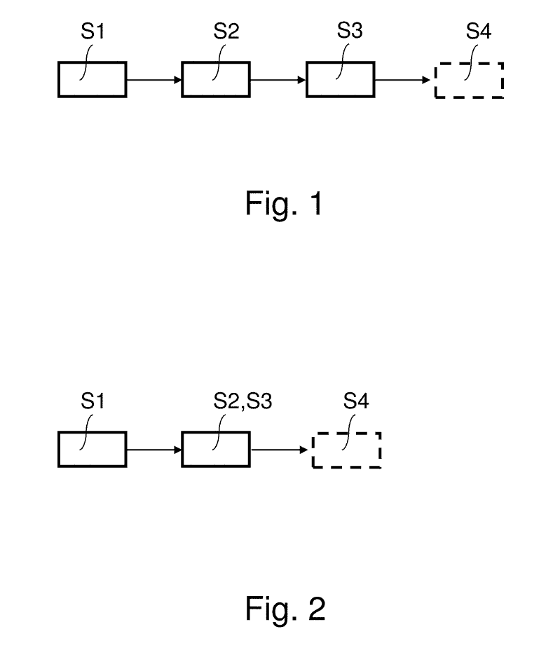

FIG. 1 depicts the sequence of a process for producing a corrosion-protected steel product according to a first working example in a schematic block diagram. In the process, a steel substrate which can be configured with a strip or plate shape is provided in a first process step S1. In a second process step S2, a metallic material is applied to the steel substrate provided in a coating operation. Coating is preferably carried out by sputtering deposition, so that a thin metallic layer can be obtained. The metallic material is preferably a transition metal, in particular chromium, titanium, niobium, vanadium, tungsten, manganese, molybdenum, tantalum, zirconium, hafnium or yttrium, or aluminum. In a third process step S3 following the second process step S2, a plasma diffusion treatment is carried out, resulting in nitrogen diffusing by means of plasma nitriding through the layer into the steel substrate. Here, the steel substrate is exposed to a nitrogen-containing gas under reduced pressure and a glow discharge, in particular a hollow cathode glow discharge, is produced. As a result, nitrogen atoms are ionized in the vicinity of the steel substrate. The positively charged nitrogen ions are accelerated toward the workpiece, impinge there with high kinetic energy and are embedded in the surface of the steel substrate. The metallic material applied in the preceding process step S2 forms a nitrogen-permeable layer, so that the nitrogen can diffuse into the steel substrate. In addition, the atoms of the metal applied to the steel substrate also diffuse into the steel substrate and form an alloy region. In this operation, metal nitrides are additionally formed close to the surface.

In a modification of the process according to the first working example, carbon is applied by sputtering deposition to the steel substrate in a fourth process step S4 following the third process step S3. This fourth process step S4 can be followed by a further process step in which a plasma diffusion treatment is carried out, for example plasma nitriding. As an alternative, the fourth process step can be carried out simultaneously with a plasma diffusion treatment.

Since the application of the metallic material and the plasma nitriding are carried out in separate, successive process steps S2, S3 in this working example, this process is also referred to as separate diffusion modification.

FIG. 2 depicts a process for producing a corrosion-protected steel product as per a second working example. In a first process step S1, an in particular strip-shaped or plate-shaped steel substrate is provided. In the process according to the second working example, the second process step S2 and third process step S3 described above in connection with the first working example are carried out simultaneously. Thus, the application of the metallic material to the steel substrate is carried out while nitrogen is diffused by plasma nitriding into the steel substrate. The above-described processes of metal diffusion and nitrogen diffusion and also nitride formation occur simultaneously. In the process according to the second working example, the application of the metallic material is preferably effected by sputtering deposition.

In a modification of the process, carbon is applied by sputtering deposition to the steel substrate in a fourth process step S4. This fourth process step S4 can be followed by a further process step in which a plasma diffusion treatment is carried out, for example plasma nitriding. As an alternative, the fourth process step can be carried out simultaneously with a plasma diffusion treatment.

The process shown in FIG. 2 is also referred to as direct diffusion modification.

In the processes described in FIG. 1 and FIG. 2, the steel substrate can be preheated before the plasma diffusion treatment carried out in process step S3, by which means the steel substrate can be brought to a temperature beneficial for the nitriding operation. The steel substrate can be preheated to a temperature in the range from 350° C. to 750° C., preferably to a temperature in the range from 420° C. to 470° C., particularly preferably to a temperature in the range from 440° C. to 460°, for example to 450° C. The preheating of the steel substrate can be carried out either before application of the metallic material in process step S2 or during the application of the metallic material in process step S2 or after the application of the metallic material in process step S2. The preheating is, for example, carried out resistively, inductively, by means of a plasma, by means of an electron beam, by means of a laser and/or by means of infrared radiation.

The processes described above with the aid of FIG. 1 and FIG. 2 make it possible to produce corrosion-protected steel products having a low contact resistance within a short process time in the range from 1 minute to 15 minutes, preferably in the range from 1 minute to 10 minutes, for example 6 minutes.

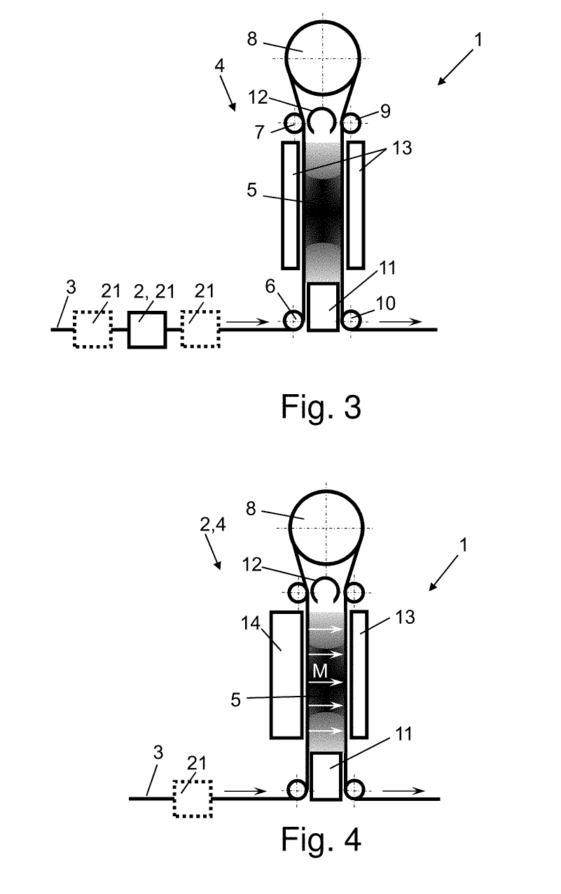

FIG. 3 shows a first working example of an apparatus 1 for producing a corrosion-protected steel product, by means of which the process shown in FIG. 1 can be realized. The apparatus 1 comprises a coating device 2 by means of which a metallic material is applied to a strip-shaped steel substrate 3 supplied to the coating device 2. The metallic layer applied to the steel substrate 3 consists of one or more transition metals (e.g. chromium, titanium, molybdenum, niobium, vanadium, etc.) or aluminum and is permeable for nitrogen diffusion during the subsequent plasma nitriding. The layer applied in the coating device 2 can further comprise carbon.

The apparatus 1 optionally comprises a preheating device 21 by means of which the steel substrate 3 is preheated. The preheating device 21 can be arranged upstream of the coating device 2 in order to preheat the steel substrate supplied to the coating device 2 or downstream of the coating device 2 in order to preheat the coated steel substrate exiting from the coating device 2. As an alternative, the preheating device 21 can be integrated into the coating device 2 so that preheating can be effected simultaneously with coating.

The apparatus 1 additionally comprises a device for plasma nitriding 4. The device for plasma nitriding 4 comprises a hollow cathode space 5 which is partly delimited by the strip-shaped steel substrate 3. For this purpose, the steel substrate 3 is conveyed by means of a transport device in such a way that two sections of the steel substrate 3, separated by the hollow cathode space 5, are arranged essentially parallel. The transport device comprises a plurality of deflection rollers 6, 7, 8, 9, 10. The strip-shaped steel substrate 3 is conveyed by means of the deflection rollers 6, 7, 8, 9, 10 through a vacuum chamber. The steel substrate is preheated to a temperature of about 450° C. before entering the device for plasma nitriding 4. The device for plasma nitriding 4 additionally comprises a gas distributor 11 via which nitrogen is introduced into the vacuum chamber, in particular into the hollow cathode space 5. An extraction device 12 is arranged on a side of the hollow cathode space 5 opposite the gas distributor 11. The gas distributor 11 is electrically connected as anode. A pulsed DC voltage in the range from 300 V to 400 V is applied between the gas distributor 11 as anode and the steel substrate as grounded cathode. As a result of the pulsed DC voltage, a hollow cathode glow discharge is formed within the hollow cathode space 5. In order to prevent spreading of the hollow cathode glow discharge to the rear side of the steel substrate 3 as far as possible, the device for plasma nitriding 4 has shields 13.

The hollow cathode glow discharge burns in the hollow cathode space 5 formed by the two sections of the steel substrate 3. The inner surface to be treated of the steel substrate 3 is in direct contact with the plasma produced by the hollow cathode glow discharge. The steel substrate 3 which has been coated with the metallic material and has been heated to the nitriding temperature enters the hollow cathode space 5 and is plasma nitrided for the first time. The steel substrate 3 continues on, is deflected by the deflection roller 8 and, without altering its temperature, once again enters the hollow cathode space 5 in which it is plasma nitrided for the second time. Here, partial or complete diffusion of the transition metals applied to the steel substrate 3 or of the carbon from the layer into the base material of the steel substrate 3 takes place in parallel to nitrogen diffusion. A surface which displays excellent corrosion resistance and electrical conductivity is achieved.

FIG. 4 depicts a second working example of an apparatus 1 for producing a corrosion-protected steel product, by means of which the process shown in FIG. 2 (direct diffusion modification) can be realized. In the apparatus 1 according to the second working example, the coating device 2 is configured as a sputtering deposition device which is arranged in such a way that simultaneous application of the metallic material and diffusion treatment by means of the apparatus for plasma nitriding 4 is possible.

The apparatus 1 according to the second embodiment optionally comprises a preheating device 21 by means of which the steel substrate 3 is preheated.

The apparatus for plasma nitriding 4 corresponds to the apparatus for plasma nitriding 4 shown in FIG. 3. In addition, a magnetic field source 14 of the coating device 2 by means of which a magnetic field M can be produced in the hollow cathode space 5 is arranged in a peripheral region of the hollow cathode space 5. The magnetic field M can be produced asymmetrically in such a way that it is present mainly in front of one of the two sections of the steel substrate 3 delimiting the hollow cathode space 5. The ions of the plasma produced by the hollow cathode glow discharge are additionally accelerated by the magnetic field M. The ions here attain a kinetic energy which is sufficient to knock metallic atoms out of the steel substrate. Thus, the steel substrate 3 is used in a section as target which is subjected to intensive sputtering. The metallic atoms detached from the first section of the steel substrate 3, for example chromium, are applied to the opposite, second section of the steel substrate 3. There, surface modification of the steel substrate 3 by metal diffusion and nitride formation takes place simultaneously with the plasma nitriding process. Thus, a self-supporting nitride formation process in which a metal, for example chromium, which assists metal nitride formation, in particular chromium nitride formation, is supplied by the treated steel substrate 3 itself is achieved according to the invention. In this way, it is possible to achieve a steel product having a surface which displays excellent corrosion resistance and electrical conductivity.

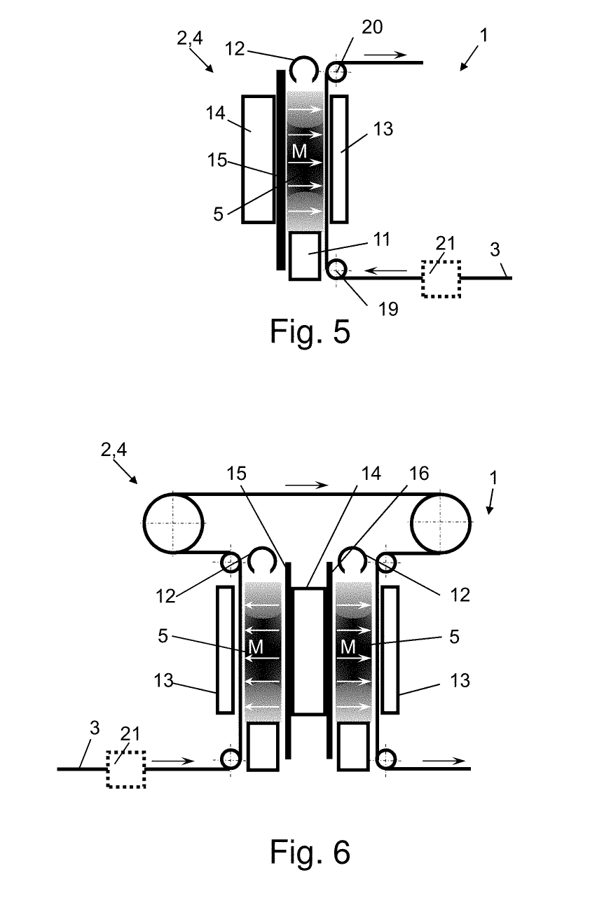

FIG. 5 shows a third working example of an apparatus 1 for producing a corrosion-protected steel product, by means of which the process shown in FIG. 2 (direct diffusion modification) can be realized. The apparatus 1 according to the third working example comprises, like the apparatus 1 according to the second working example, a magnetic field source 14 by means of which it is possible to produce a magnetic field M in the hollow cathode space 5. In contrast to the apparatus 1 of the third working example, this apparatus 1 comprises a target 15 composed of a metallic material. The hollow cathode glow discharge burns in the hollow cathode space 5 formed by the target 15 and the section of the steel substrate 3 opposite the target. The apparatus comprises a first deflection roller 19 and a second deflection roller 20 by means of which the steel substrate 3 is conveyed in such a way that it delimits one side of the hollow cathode space 5. In a continuous strip process, the steel substrate 3 enters the hollow cathode glow discharge and is surface-treated there: in parallel to plasma nitriding, the material is sputtered from the opposite target 15 as a result of the magnetic field M and the sputtered material (e.g. chromium, titanium, molybdenum, niobium, vanadium, etc.) reaches the opposite section of the steel substrate 3. There, surface modification of the steel substrate 3 takes place by metal diffusion and nitride formation simultaneously with the plasma nitriding process, so that a surface which displays excellent corrosion resistance and electrical conductivity is produced.

The apparatus 1 according to the third working example optionally comprises a preheating device 21 by means of which the steel substrate 3 is preheated.

In a modification of the apparatus 1 shown in FIG. 5 for producing a corrosion-protected steel product, the first apparatus 1 is followed by a second apparatus which comprises a target 15 consisting of graphite. The steel substrate 3 which has been treated by application of metal and plasma nitriding exiting from the first apparatus 1 can be doped with carbon in the second apparatus and at the same time plasma nitrided once more. The carbon doping contributes to further stabilization of the corrosion resistance and the contact resistance of the steel substrate in the typical operating range of a fuel cell (polarization: −0.2 V(SHE) to +1.2 V(SHE); temperature: 80° C.; 0.1 M sulfuric acid).

FIG. 6 shows a fourth working example of an apparatus 1 for producing a corrosion-protected steel product. The apparatus 1 according to the fourth working example comprises precisely two hollow cathode spaces 5 which are partly delimited by a section of the steel substrate 3. A target 15, 16 is in each case arranged on a side of the hollow cathode space 5 opposite the section of the steel substrate 3. Furthermore, the apparatus 1 comprises one or more magnetic field sources 14 which produce a magnetic field M in the two hollow cathode spaces 5, as a result of which material is removed both from the first target 15 and from the second target 16. In this apparatus 1, the first target is made of a metallic material and the second target 16 is made of graphite. In a continuous process, the strip-shaped steel substrate 3 enters the first hollow cathode space 5 and is surface-treated there: in parallel to plasma nitriding, the metal target 15 is sputtered and the sputtered material (e.g. chromium, titanium, molybdenum, niobium, vanadium, etc.) reaches the opposite section of the steel substrate 3. There, surface modification of the steel substrate 3 by metal diffusion and nitride formation takes place simultaneously with the abovementioned plasma nitriding process. The steel substrate 3 then enters the second hollow cathode space 5 and is surface-treated for the second time: in parallel to plasma nitriding, the graphite target 16 is sputtered and the sputtered carbon reaches the opposite section of the steel substrate 3. There, surface modification by doping with carbon takes place simultaneously with a plasma nitriding process.

The apparatus 1 according to the fourth working example optionally comprises a preheating device 21 by means of which the steel substrate 3 is preheated.

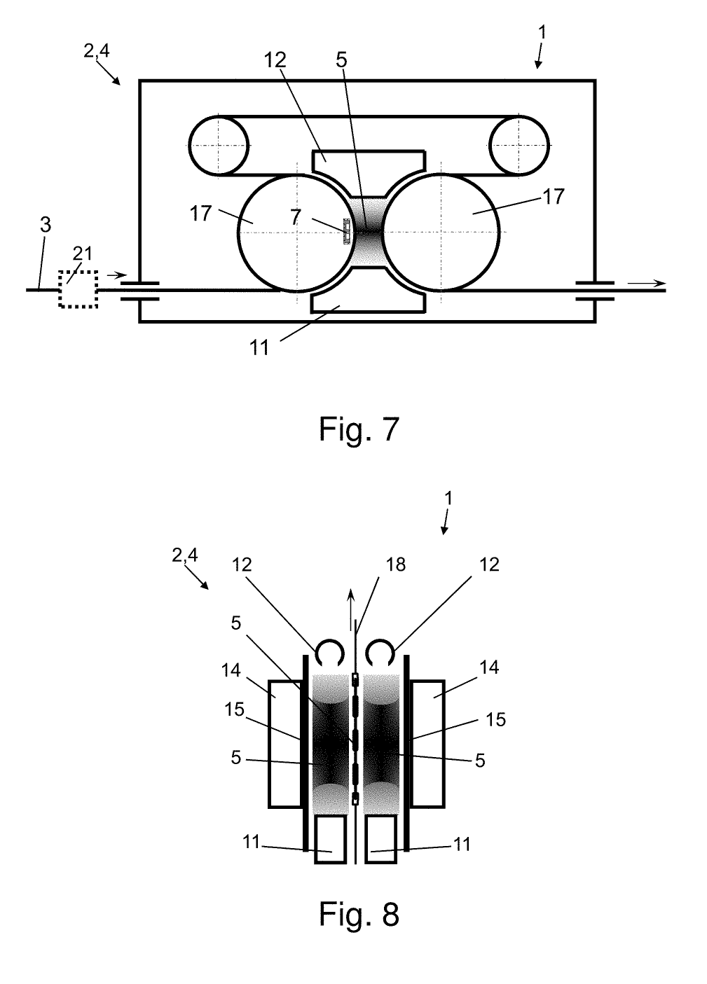

FIG. 7 shows a fifth working example of an apparatus 1 for producing a corrosion-protected steel product. In contrast to the apparatuses shown in FIGS. 3-6, the apparatus 1 according to FIG. 7 comprises two guide rollers 17 by means of which the steel substrate 3 is conveyed in such a way that it delimits the hollow cathode space 5 in an arc-like manner in the region of the guide roller 17. The steel substrate 3 lies directly against the guide roller 17. This prevents spreading of the hollow cathode glow discharge to the side of the steel substrate 3 facing the guide roller 17. It is therefore possible to use a stable glow discharge having a significantly higher discharge power. During plasma nitriding, a significantly higher plasma nitriding rate is achieved as a result of the higher discharge power, which makes it possible to carry out the process at an increased speed. Since the use of high discharge powers can lead to a strip temperature, the guide rollers 17 are configured so as to be coolable so that temperature control of the steel substrate 3 can be effected by means of the guide rollers 17. A magnetic field source 14 is arranged within a guide roller 17. This enables sputtering deposition in the hollow cathode space 5 with arc-like delimitation.

The apparatus 1 according to the fifth working example optionally comprises a preheating device 21 by means of which the steel substrate 3 is preheated.

FIG. 8 depicts a sixth working example of an apparatus 1 according to the invention having two hollow cathode spaces 5, which is suitable for producing plate-shaped steel products. The apparatus 1 comprises a holding device 18 by means of which the steel substrate 3 can be introduced into the apparatus 1 in such a way that the steel substrate 3 is arranged between two hollow cathode spaces 5 and delimits the two hollow cathode spaces 5. A magnetic field source 14 which produces a magnetic field M in the hollow cathode space 5 is assigned to each hollow cathode space 5. A target 15 is arranged on each side of the hollow cathode spaces 5 which are opposite the steel substrate 3. Parallel to plasma nitriding, the two targets 15 are sputtered and the sputtered metallic material (e.g. chromium, titanium, molybdenum, niobium, vanadium, etc.) reaches the steel substrate 3 on the opposite side of the hollow cathode space 5. There, surface modification of the steel substrate by metal diffusion and nitride formation takes place simultaneously with the plasma nitriding process. Furthermore, the surfaces of the two sides of the bipolar plate can optionally be carbon-doped. For this purpose, it is possible to use a second apparatus 1 which comprises two targets composed of graphite.

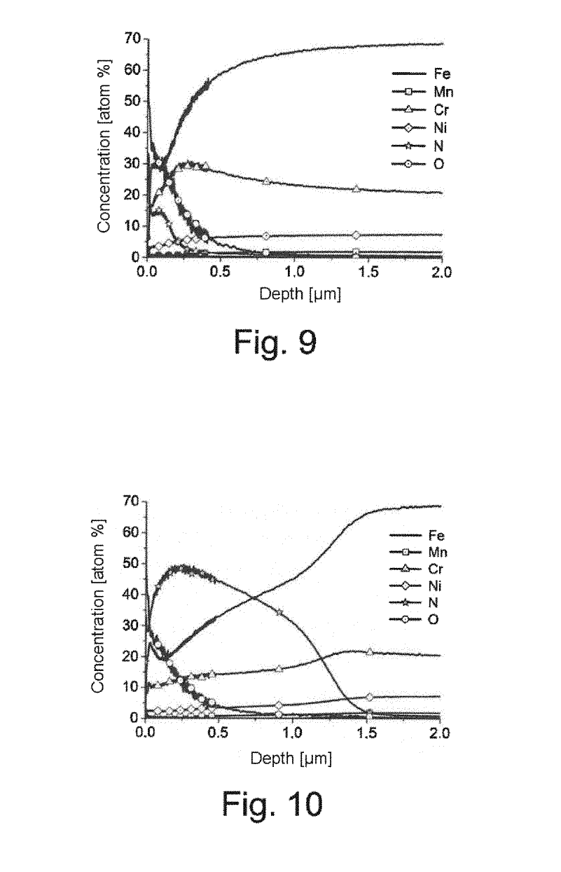

In the following, corrosion-protected steel products which have been produced by a process as per FIG. 2 using an apparatus as per FIG. 5 will be described with the aid of the depictions in FIGS. 9 to 12. An austenitic, rusting- and acid-resistant steel substrate having a thickness of 0.1 mm and the material number EN-1.4301 was used as starting material. The process conditions and process parameters are summarized in Table 1. The distance between the target and the steel substrate was 30 mm, and the selected working pressure in the apparatus is in the range from 4 Pa to 7 Pa. A pulsed direct current having a discharge frequency of 145 kHz and a pulse pause of 3.1 μs was used.

TABLE 1

| | Gas flow | | | | Hollow cathode | | |
|---|---|---|---|---|---|---|---|
| | rate, | | Substrate | Dura- | glow discharge | | |
| Steel | sccm | | tempera- | tion, | Voltage, | Current, | Power, |
| product | H₂ | N₂ | ture, ° C. | s | V | A | W |
| A | 700 | 700 | 450 | 360 | 350 | 2.10 | 725 |
| B | 40 | 120 | | | 339 | 1.46 | 495 |
| C | 40 | 120 | | | 370 | 1.52 | 563 |

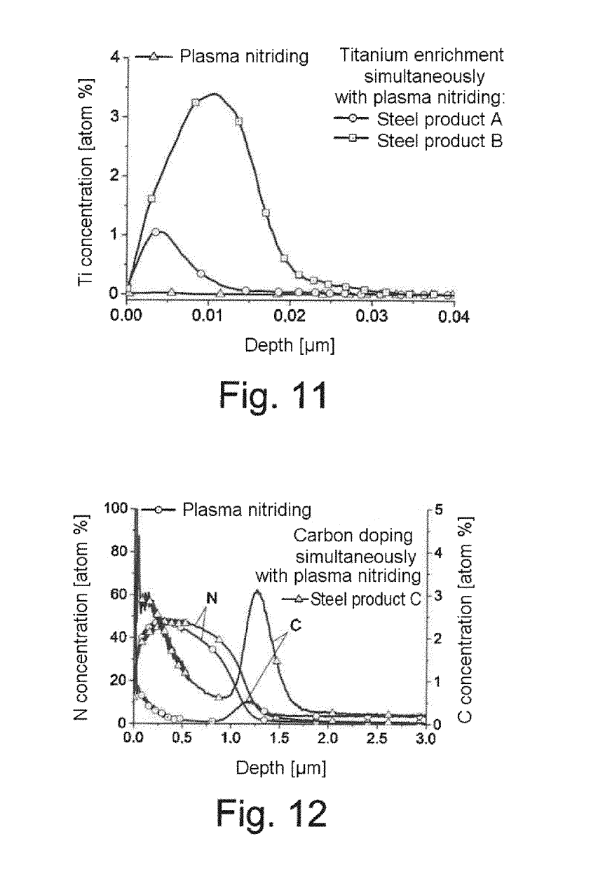

The depth profiles of the steel products produced which are shown in FIGS. 9 to 12 were determined by means of glow discharge optical emission spectroscopy (GDOES). A target 15 composed of titanium was used for producing the steel products A and B. As can be seen from the graphical depictions in FIGS. 10 and 11, the steel product A displays a concentration depth distribution of nitrogen and titanium in the near-surface region of the nitrided diffusion layer which is typical of plasma nitriding. In contrast, the steel product B has a greatly reduced nitriding depth and a low surface concentration of nitrogen (FIG. 9) and also a significantly higher titanium content (FIG. 11). The amounts of titanium determined are 0.8 mg·m⁻² for the steel product A and 4.5 mg·m⁻² for the steel product B. As can also be seen from FIG. 11, the amount of titanium in a process which comprises plasma nitriding without additional application of titanium (reference) is less than 0.1 mg·m⁻². A significant enrichment of titanium in the near-surface region compared to the prior art is therefore observed.

The production of the steel product C was carried out using a graphite target, cf. FIG. 12. Compared to the reference plasma nitriding, a significantly higher carbon concentration is found both in the region close to the surface and at the interface between the nitriding layer and the base material in the case of the steel product C.

Corrosion-protected steel products can be produced by means of the above-described processes and apparatuses, in the case of which a steel substrate is provided, nitrogen is diffused by plasma nitriding into the steel substrate and a metallic material is additionally applied to the steel substrate. This makes it possible to obtain a steel product having a surface which has improved corrosion resistance and a low contact resistance, so that the steel product can also be used as bipolar plate under the operating conditions prevailing in a fuel cell.

### LIST OF REFERENCE SYMBOLS

1 Apparatus for producing a corrosion-protected steel product
2 Coating device
3 Steel substrate
4 Apparatus for plasma nitriding
5 Hollow cathode space
6 Deflection roller
7 Deflection roller
8 Deflection roller
9 Deflection roller
10 Deflection roller
11 Gas distributor
12 Extraction device
13 Shielding
14 Magnetic field source
15 Target
16 Target
17 Guide roller
18 Holding device
19 Deflection roller
20 Deflection roller
21 Preheating device
M Magnetic field
S1 Provision
S2 Application of a metallic material
S3 Plasma nitriding
S4 Application of carbon

1. An apparatus for producing a corrosion-protected steel product, the apparatus comprising:
a device for plasma nitriding a steel substrate, wherein the plasma nitriding device comprises at least one hollow cathode space in which a hollow cathode glow discharge is produced; and
a coating device for applying a metallic material to the steel substrate,
wherein the hollow cathode space is delimited at least partly by the steel substrate.

2. The apparatus as claimed in claim 1, wherein the coating device is a sputtering deposition device.

3. The apparatus as claimed in claim 2, wherein the sputtering deposition device comprises a magnetic field source to produce a magnetic field in the hollow cathode space.

4. The apparatus as claimed in claim 2, wherein the sputtering deposition device comprises a target from which metal atoms can be detached, and wherein the target is formed by the steel substrate.

5. The apparatus as claimed in claim 1, wherein the plasma nitriding device comprises a guide roller via which the steel substrate is conducted in such a way that the steel substrate delimits the hollow cathode space in an arc-like manner in the region of the guide roller.

6. The apparatus as claimed in claim 5, wherein a magnetic field source for producing a magnetic field in the hollow cathode space is arranged within the guide roller.

7. The apparatus as claimed in claim 1, wherein the plasma nitriding device comprises two hollow cathode spaces.

8. The apparatus as claimed in claim 1, wherein the apparatus comprises a holding device to introduce the steel substrate into the apparatus in such a way that the steel substrate is arranged between two hollow cathode spaces and delimits the two hollow cathode spaces.

9. The apparatus as claimed in claim 1, wherein the apparatus comprises a preheating device to preheat the steel substrate before plasma nitriding.

10. A process for producing a corrosion-protected steel product, comprising:
providing a steel substrate;
diffusing nitrogen by plasma nitriding into the steel substrate, wherein a plasma is provided by a hollow cathode glow discharge in a hollow cathode space to effect plasma nitriding;
applying a metallic material to the steel substrate; and
wherein the hollow cathode space is at least partly delimited by the steel substrate.

11. The process as claimed in claim 10, wherein the metallic material is applied by sputtering deposition.

12. The process as claimed in claim 10, wherein the metallic material comprises a transition metal comprising one of chromium, titanium, niobium, vanadium, tungsten, manganese, molybdenum, tantalum, zirconium, hafnium or yttrium, and aluminum.

13. The process as claimed in claim 10, wherein the metallic material is applied before nitrogen is diffused by plasma nitriding into the steel substrate.

14. The process as claimed in claim 10, wherein the metallic material is applied while nitrogen is diffused by plasma nitriding into the steel substrate.

15. The process as claimed in claim 10, wherein carbon is applied by sputtering deposition to the steel substrate after nitrogen has diffused by plasma nitriding into the steel substrate.

16. The process as claimed in claim 10, wherein the steel substrate is conveyed during inward diffusion of nitrogen and the application of the metallic material.

17. The process as claimed in claim 10, wherein the hollow cathode glow discharge is provided by a pulsed DC voltage.

18. The process as claimed in claim 10, wherein the steel substrate is made of at least one of an austenitic and rusting and acid resistant steel.

19. The process as claimed in claim 10, wherein the steel substrate is preheated to a temperature in the range from 350° C. to 750° C. before plasma nitriding.

20. The process as claimed in claim 19, wherein the steel is preheated to a temperature in the range of 420° C. to 470° C. before plasma nitriding.

21. The process as claimed in claim 19, wherein the steel is preheated to a temperature in the range of 440° C. to 460° C. before plasma nitriding.

22. The process as claimed in claim 19, wherein the steel is preheated to a temperature of 450° C. before plasma nitriding.
